(19) United States
(12) Patent Application Publication
(10) Pub. No.: US 2025/0308841 A1
(43) Pub. Date: Oct. 2, 2025

(54) DOPANT DELIVERY SYSTEM TO ION SOURCE USING INDUCTION HEATING

(71) Applicant: Axcelis Technologies, Inc., Beverly, MA (US)

(72) Inventors: Vladimir Romanov, Danville, NH (US); Vladimir Gorelik, Woburn, MA (US); Ilya Pokidov, Winchester, MA (US); Neil Bassom, Hamilton, MA (US); David Sporleder, Billerica, MA (US); Joseph Valinski, Newmarket, NH (US); Edward Moore, Newmarket, NH (US)

(21) Appl. No.: 19/091,903

(22) Filed: Mar. 27, 2025

Related U.S. Application Data
(60) Provisional application No. 63/570,346, filed on Mar. 27, 2024.

(51) Int. Cl. H01J 37/317; H01J 37/08; H01J 37/32; H05B 6/04; H05B 6/08; H05B 6/24

(52) U.S. Cl. CPC H01J 37/3171; H01J 37/08; H01J 37/32467; H01J 37/32935; H05B 6/04; H05B 6/08; H05B 6/24

(57) ABSTRACT

An ion source has an arc chamber defining an arc chamber volume. An inductively heated dopant material source is in fluid communication with the arc chamber volume, and has a crucible containing a dopant species and an inductive heater. An induction heater power supply is coupled to the inductive heater to supply an induction current to the induction heater. A controller controls the induction current such that the inductive heater heats the dopant species to a predetermined temperature based on the induction current and selectively flows the dopant species from the crucible to the arc chamber volume. A material monitoring system determines an amount of the dopant species in the crucible based on an induction current supplied to the induction heater. An intermediary receptor can be heated in the crucible by the induction heater to aid a melting of the dopant species within the crucible.

### REFERENCE TO RELATED APPLICATIONS

This application claims the benefit of U.S. Provisional Application Ser. No. 63/570,346 filed Mar. 27, 2024, entitled, “DOPANT DELIVERY SYSTEM TO ION SOURCE USING INDUCTION HEATING”, the contents of all of which are herein incorporated by reference in their entirety.

### TECHNICAL FIELD

The present invention relates generally to ion implantation systems, and more specifically to an ion source having an inductive dopant material source configured to provide a dopant to an arc chamber.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

There is increasing demand for ion implants using metal ions. For example, aluminum implants are important for the power device market, which is a small but very fast-growing segment of the market. For many metals, including aluminum, supplying feed material to the ion source is problematic. While gas molecules containing aluminum or other metals may be utilized, the metal atom(s) tend to be attached to numerous carbon and/or hydrogen atoms, which can cause problems in the ion source. Systems have been previously provided that utilize a vaporizer, which is a small oven that is external to the arc chamber of the ion source, whereby metal salts are heated to produce adequate vapor pressure to supply vapor to the ion source. The oven, however, is typically heated by resistive heating, which takes a significant time to heat up to the desired temperature, establish the vapor flow, start the plasma, start the ion beam, etc. Further, if a change from one metal species to some other species is desired, time is taken in waiting for the oven to cool down adequately for such a change in species so that the vapor from the vaporizer is no longer present in the arc chamber to an appreciable degree.

### SUMMARY

The following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate ion implantation processes for implanting ions into a workpiece. According to one example, an ion implantation system is provided having an ion source configured to form an ion beam, a beamline assembly configured to selectively transport the ion beam, and an end station configured to accept the ion beam for implantation of the ions into a workpiece.

In accordance with one exemplary aspect, an ion source is provided having an arc chamber defining an arc chamber volume. An inductively heated dopant material source is in fluid communication with the arc chamber volume, wherein the inductively heated dopant material source comprises a crucible and an inductive heater, wherein the crucible is configured to contain a dopant species therein. An induction heater power supply electrically coupled to the inductive heater, wherein the induction heater power supply is configured to selectively supply an induction current to the induction heater. Further, a controller is configured to control the induction current via a control of the induction heater power supply, wherein the inductive heater selectively heats the dopant species to a predetermined temperature based, at least in part, on the induction current to selectively permit a flow of the dopant species from the crucible to the arc chamber volume.

In one example, the crucible comprises an inner vessel configured to contact the dopant species, wherein the inductive heater is configured selectively inductively heat the dopant species through the inner vessel. The crucible, for example, can further comprise an outer shell generally surrounding the inner vessel, and wherein the inductive heater is configured selectively heat the dopant species through the outer shell. The inner vessel, for example, can be comprised of a first ceramic, and wherein the outer shell is comprised of a thermally and electrically insulating material. In another example, one or more of the inner vessel and the outer shell comprises one or more of boron nitride, alumina, silicon carbide, beryllium oxide, magnesium oxide, zirconia, or a machinable glass ceramic.

In accordance with another example, the ion source further comprises a conduit, wherein the inductively heated dopant material source is positioned external to the arc chamber, wherein the conduit fluidly couples the inductively heated dopant material source to the arc chamber, and wherein the conduit is configured to introduce the dopant species to the arc chamber volume in one of a liquid phase or a vapor phase. A cup, for example, can be positioned within the chamber arc volume, wherein the conduit is configured to introduce the dopant species to the arc chamber volume in the liquid phase.

In another example, the inductively heated dopant material source comprises a vaporizer, wherein the inductive heater is configured to vaporize the dopant species at the predetermined temperature in the crucible within the vaporizer to define a vaporized dopant species, and wherein the conduit is configured to introduce the vaporized dopant species to the arc chamber volume.

The ion source, for example, can further comprise a reactive gas source configured to selectively supply a reactive gas to the crucible, wherein the reactive gas is configured to react with a material associated with the dopant species, thereby purifying the dopant species.

In accordance with another example, the controller further comprises a material monitoring system configured to determine an amount of the dopant species contained in the crucible, wherein the amount of the dopant species contained in the crucible is associated with the induction current supplied to the induction heater. The material monitoring system, for example, can comprise a Kalman Filtering algorithm to model the amount of the dopant species contained in the crucible.

In accordance with another aspect of the disclosure, the ion source can further comprise an intermediary receptor positioned within the crucible, wherein the induction heater is configured to inductively heat the intermediary receptor, and wherein the intermediary receptor is configured to aid a melting of the dopant species within the crucible. The dopant species, for example, can be electrically non-conductive, wherein the intermediary receptor is electrically conductive. The intermediary receptor, for example, can have a receptor density, whereby the dopant species further has a dopant density, wherein the receptor density is greater than the dopant density, and wherein the intermediary receptor comprises a receptor plate associated with a bottom of the crucible. The intermediary receptor can comprise one of a refractory material or graphite. In another example, the receptor density is less than the dopant density, wherein the intermediary receptor comprises a plurality of small bodies. The ion source, for example, can further comprise an electromagnetic field generator configured to generate an electromagnetic field associated with the crucible, wherein the plurality of small bodies are configured to vibrate based on a selective variation in the electromagnetic field provided by the electromagnetic field generator.

In accordance with yet another example, the controller is further configured to control a frequency of the induction current, whereby the frequency controls a speed of the heating of the dopant species. The frequency, for example, is in one of a high frequency of approximately 200 kHz at a 1.5 km wavelength associated with a fast melting of the dopant species and a low frequency of approximately 5 kHz at a 60 km wavelength associated with a slow melting of the dopant species.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a block diagram of an ion implantation system having an inductively heated crucible for an ion source material in accordance with several examples of the present disclosure.

FIG. 2 is a block diagram of an ion source having inductive heated crucible in accordance with various examples of the present disclosure.

FIG. 3 is a perspective view of an inductively heated dopant material source in accordance with various examples of the present disclosure.

FIG. 4 is a cross-sectional view of dopant material source of an inductively heated dopant material source in accordance with various examples of the present disclosure.

FIGS. 5A-5C are respective perspective views of an inductively heated dopant material source having one or more intermediary receptors in accordance with various examples of the present disclosure.

FIG. 6 is a graph of induction heater current versus mass for a gallium dopant species in accordance with various examples of the present disclosure.

FIG. 7 is a graph of induction heater current versus mass for an aluminum dopant species in accordance with various examples of the present disclosure.

FIG. 8 is a graph illustrating an example vapor pressure curve for various dopant species in accordance with various examples of the present disclosure.

### DETAILED DESCRIPTION

The present disclosure is directed generally toward ion implantation systems, methods, and apparatuses for implantation of ions into a workpiece. More particularly, the present disclosure is directed toward an ion source having an inductively heated vaporizer configured to selectively melt and/or vaporize a solid source material to liquid or gaseous form and to selectively provide the source material to an arc chamber for producing ions to electrically or otherwise modify silicon, silicon carbide, or other semiconductor substrates at various temperatures.

Accordingly, the present invention will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features, circuits, or components in one embodiment, and may also or alternatively be fully or partially implemented in a common feature, circuit, or component in another embodiment. Further, several functional blocks, for example, may be implemented as software running on a common processor or controller.

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the workpiece with impurities of a specified dopant material, at a predetermined energy level, and in controlled concentration, to produce a desired semiconductor material during fabrication of an integrated circuit. When used for doping a semiconductor wafer, for example, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

An ion implanter includes an ion source, an ion extraction device, a mass analysis device, a beam transport device and a workpiece processing device. The ion source generates ions of desired atomic or molecular dopant species. These ions are extracted from the ion source by an extraction system, such as a set of electrodes which energize and direct the flow of ions from the ion source, forming an ion beam. Desired ions are separated from the ion beam in a mass analysis device, such as a magnetic dipole that performs mass dispersion or separation of the extracted ion beam. The beam transport device, such as a vacuum system containing a series of focusing devices, transports the ion beam to the workpiece processing device while maintaining desired properties of the ion beam. Finally, workpieces such as semiconductor wafers are transferred in to and out of the workpiece processing device via a workpiece handling system, which may include one or more robotic arms for placing a workpiece to be treated in front of the ion beam and removing the treated workpiece from the ion implanter.

There is increasing demand for implanting ion species extending beyond the conventional boron, arsenic, and phosphorous implants that have historically been used to dope semiconductors. For power devices, aluminum can be used in place of boron as a p-type dopant due to its low diffusivity in silicon carbide. Alternative metals such as lanthanum, yttrium, iridium, gallium, and platinum, for example, are presently under investigation for silicon devices. While some of the alternative metals (e.g., gallium) melt at temperatures that are encountered in an ion source, other alternative metals have higher melting points than those present in the ion source. Species used in semiconductor fabrication processes having melting points above about 650° C., for example, cannot be used in a conventional vaporizer having resistive or lamp-based heating elements.

A vaporizer can further operate using salts of a desired implant species, such as fluorides, chlorides, or oxides of the desired species. For example, the present disclosure contemplates the use of salts of a desired implant species, such as fluorides, chlorides, or oxides of aluminum (AI), lanthanum (La), cerium (Ce), platinum (Pt), neodymium (Nd), germanium (Ge), bismuth (Bi), silver (Ag), lead (Pb), lithium (Li), tellurium (Te), zinc (Zn), strontium (Sr) magnesium (Mg), gold (Au), copper (Cu) samarium (Sm), europium (Eu), terbium (Tb), dysprosium (Dy), holmium (Ho), erbium (Er) ytterbium (Yb), gallium (Ga), indium (In), tin (Sn), sulfur(S), and selenium (Se). In using salts in the ion source, however, it is appreciated that unwanted atoms associated with such salts can be injected into the ion source along with atoms of the desired species.

Therefore, the present disclosure appreciates that various advantages can be achieved in supplying the ion source with atoms of only the desired implant species. Accordingly, the present disclosure provides various performance advantages for ion implantation systems, including, but not limited to reducing a cost associated with the ion implantation system, an increase in power efficiency and throughput, an improvement to purity of the ion beam, and reducing downtime associated with the ion implantation system.

The present disclosure thus provides systems, methods, and apparatuses configured for the utilization of induction heating for melting feed materials, whereby the feed materials may be pure metals, compounds, or even salts, whereby utilizing the presently disclosed induction heating can increase a utility of the ion implantation system. For example, the induction heating provided by the present disclosure can achieve high temperatures that may be limited only by a temperature rating of components surrounding the ion source.

Co-owned U.S. Pat. No. 11,728,140, the contents of which is incorporated by reference in its entirety, discusses a generation of ions from low-temperature melting metals, such as Al, Ga, In, Sn, etc. in a liquid metal ion source (LMIS) for an ion implantation system, whereby a hydraulic feed system provides the melted metal to an ion source. Metals having a melting point above 600° C., however, can be difficult to melt and/or use in such a liquid metal ion source due to the failure of a ceramic crucible and resistive heating elements associated therewith. For example, the metal or material is heated by a transfer of power that is developed remote from the material (e.g., a resistive cartridge heater located at a substantial distance from the material to be melted), whereby substantial power can be lost or transferred away.

The present disclosure further appreciates that efforts have been made by using material that is held inside a cup-shaped repeller within the arc chamber, where the repeller is covered by a cap having holes penetrating through the cap, such as disclosed in co-owned U.S. Pat. No. 11,170,967, the contents of which are herein incorporated by reference in its entirety. Such an approach uses a combination of vaporization of the material to supply a gas, and surface tension to draw the liquid to the surface of the cap to be exposed to the plasma in order to feed liquid material directly into the ion source chamber. Such an approach has demonstrated high current capabilities. However, the amount of material that can be held in the cup is limited, and control of the flow of the liquid is difficult and is influenced by the plasma parameters. Further, it may be difficult to quickly start or halt the flow of material from the cup if a different species is desired to be run, and such an approach is best suited to systems where an axis defined between the cathode and repeller is vertical.

The present disclosure appreciates a desire to provide a system, apparatus, and method to achieve quick control of an introduction or flow of a dopant species, such as a pure elemental metal, into an ion source from a crucible having a capacity that is large enough to last at least a lifetime of the ion source, and wherein a fast-switching capability is provided for changing between different ion species.

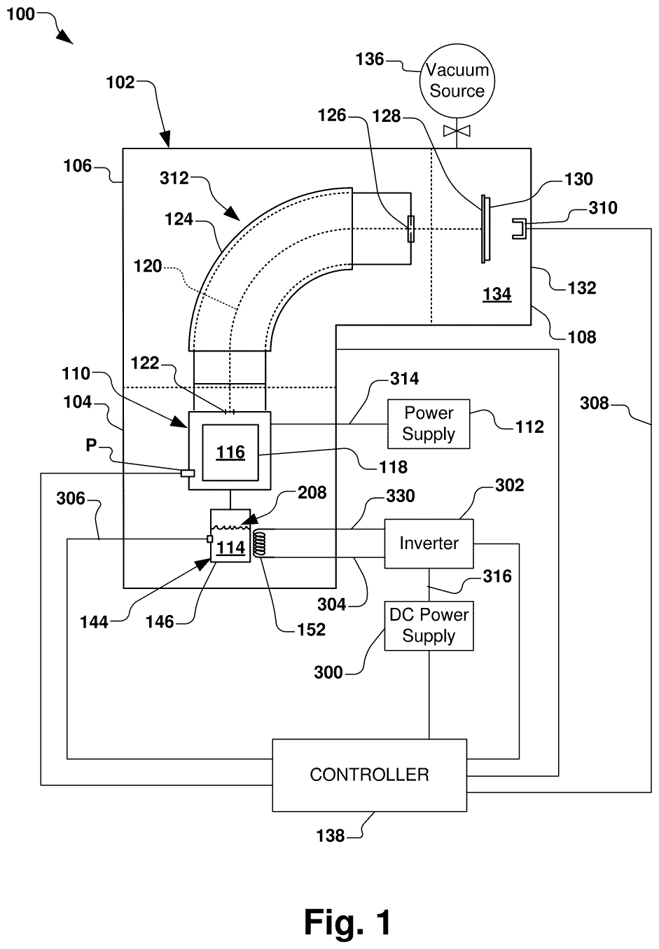

In order to gain a general understanding and context of the invention, FIG. 1 illustrates an exemplary vacuum system 100. The vacuum system 100 in the present example comprises an ion implantation system 102, however various other types of vacuum systems are also contemplated, such as plasma processing systems, or other semiconductor processing systems. The ion implantation system 102, for example, comprises a terminal 104, a beamline assembly 106, and an end station 108.

Generally speaking, an ion source 110 in the terminal 104 is coupled to a power supply 112, whereby a supply of source material 114 (also called a dopant material or dopant species) is provided to an arc chamber volume 116 within an arc chamber 118 and is ionized into a plurality of ions to form and extract an ion beam 120 via an extraction electrode 122. The ion beam 120 in the present example is directed through a beam-steering apparatus 124 (also called a source magnet), and out an aperture 126 towards the end station 108. In the end station 108, the ion beam 120 bombards a workpiece 128 (e.g., a semiconductor such as a silicon wafer, a display panel, etc.), which is selectively clamped or mounted to a chuck 130 (e.g., an electrostatic chuck or ESC). Once embedded into the lattice of the workpiece 128, the implanted ions change the physical and/or chemical properties of the workpiece. Because of this, ion implantation is used in semiconductor device fabrication and in metal finishing, as well as various applications in materials science research.

The ion beam 120 of the present disclosure can take any form, such as a pencil or spot beam, a ribbon beam, a scanned beam, or any other form in which ions are directed toward end station 108, and all such forms are contemplated as falling within the scope of the disclosure.

According to one exemplary aspect, the end station 108 comprises a process chamber 132, (e.g., a vacuum chamber), wherein a process environment 134 is associated with the process chamber. The process environment 134 generally exists within the process chamber 132, and in one example, comprises a vacuum produced by a vacuum source 136 (e.g., a vacuum pump) coupled to the process chamber and configured to substantially evacuate the process chamber. Further, a controller 138 is provided for overall control of the vacuum system 100 and components, thereof.

It shall be understood that the systems, apparatuses, and methods of the present disclosure may be implemented in other semiconductor processing equipment such as CVD, PVD, MOCVD, etching equipment, and various other semiconductor processing equipment, and all such implementations are contemplated as falling within the scope of the present disclosure. The present disclosure provides systems, apparatuses, and methods to advantageously increase the length of usage of the ion source 110 between preventive maintenance cycles, and thus increasing overall productivity and lifetime of the vacuum system 100.

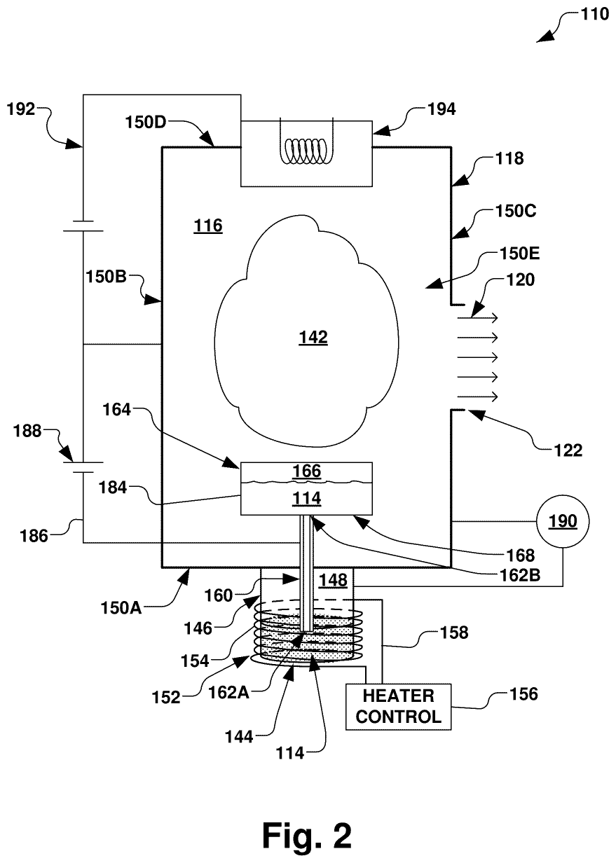

The arc chamber 118 of the ion source 110, for example, is schematically illustrated in FIG. 2, whereby the ion source of the present disclosure can be configured to provide the ion beam 120 of FIG. 1, whereby a high beam current can be attained by supplying the source material 114 to the arc chamber in a pure, elemental, and solid form. For example, in accordance with the present disclosure, the source material 114 can be initially provided to the ion source 110 of FIG. 2 in solid form, and can be comprised of elemental aluminum, indium, gallium, lanthanum, tin, antimony, or other element that is useful for ion implantation. For example, either a pure elemental material may be used, or an alloy may be preferred if the alloy has a more convenient melting temperature. It is noted further that while the source material 114 is described in one example as being an elemental metal, it is noted that the source material can comprise any metallic or non-metallic element, combination elements, salts, or compounds, and any such source material is contemplated as falling within the scope of the present disclosure.

As illustrated in FIG. 2, the arc chamber 118 generally defines the arc chamber volume 116 in which a plasma 142 is formed from the source material 114. In accordance with one example embodiment, an inductively heated dopant material source 144 is operably coupled to the arc chamber 118. The inductively heated dopant material source 144, for example, comprises a crucible 146 that generally defines a crucible volume 148, whereby the crucible volume is in fluid communication with the arc chamber volume 116. The crucible 146, for example, is configured to contain the source material 114 in one or more of a solid form, a liquid form, or a gas form within the crucible volume 148.

In accordance with one example, the crucible 146 is selectively coupled to one or more sidewalls 150A-150E of the arc chamber 118. In the present example, the crucible 146 is operably coupled to a bottom sidewall 150A of the arc chamber 118. It should be noted, however, that the crucible 146 may be operably coupled to any of the one or more sidewalls 150A-150E (e.g., bottom, top, left, right, front, back, or other wall) of the arc chamber 118, whereby the crucible can be directly or indirectly coupled to the one or more sidewalls, and can be either stationary or translational with respect to the arc chamber. In other examples, the crucible 146 may be separate from the arc chamber 118.

The crucible volume 148, for example, is selectively accessible for selective placement and enclosure of the source material 114 (e.g., in solid form), therein. In the present example, the crucible 146 can be selectively operably coupled to the arc chamber 118, such as via one or more bolts, latches, screws, levers, plates, or other coupling devices, whereby the crucible volume 148 may be selectively accessed. For example, the crucible 146 can be selectively removed from the arc chamber 118, whereby the source material 114 can be placed within the crucible volume 148, and then the crucible can again be coupled to the arc chamber.

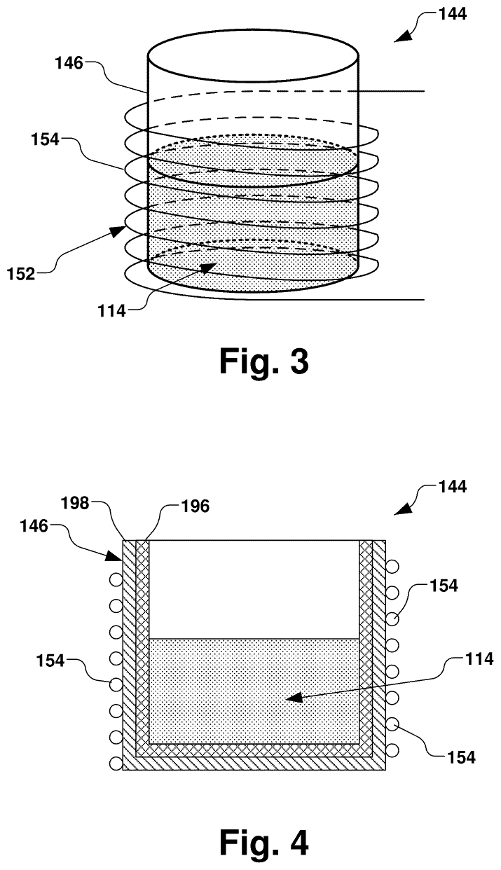

In accordance with the present disclosure, the inductively heated dopant material source 144 further comprises an inductive heater 152, whereby the inductive heater is configured to inductively heat the crucible 146, as illustrated in FIG. 3. The inductive heater 152, for example, comprises an induction coil 154 (e.g., one or more coiled wires) generally encircling or surrounding the crucible, and configured to selectively heat the source material 114 positioned within the crucible 146 to a predetermined temperature. The predetermined temperature, for example, is approximately equal to, or greater than, one of a melting point or a boiling point of the selected source material 114 placed within the crucible volume 148.

Referring again to FIG. 2, an induction heater control apparatus 156, for example, is electrically coupled to the induction coil 154 of the inductive heater 152, whereby the predetermined temperature associated with the inductive heater 152 is controllable. The induction heater control apparatus 156, for example, is configured to selectively supply an induction current 158 to the induction heater 152, whereby the induction coil 154 is configured to inductively heat the source material 114 within the crucible 146 without being in contact with the source material. For example, the induction heater control apparatus 156 is configured to selectively provide the induction current 158 to the induction coil 154 of the induction heater 152 to provide an alternating electromagnetic field that induces eddy currents to generate heat within the source material 114. In accordance with another example, FIG. 2 illustrates a conduit 160 fluidly coupling the crucible volume 148 to the arc chamber volume 116. It is noted that while the inductively heated dopant material source 144 is illustrated as being coupled to the bottom sidewall 150A of the arc chamber 118, the inductively heated dopant source can be provided as a stand-alone vaporizer (not shown), whereby the conduit fluidly couples the vaporizer to the arc chamber volume 116, and all such variations are contemplated as falling within the scope of the present disclosure. In the present example, the conduit 160 comprises a first opening 162A and a second opening 162B, wherein the first opening is operably coupled to the crucible 146 and open to the crucible volume 148, and wherein the second opening is vertically elevated from the first opening and open to the arc chamber volume 116. The induction heater control apparatus 156, for example, can be thus configured to selectively supply the source material 114 from the crucible volume 148 when the source material has been heated to one of a liquid state or gaseous state.

In one example, a cup 164 is further positioned within the arc chamber 118, wherein the cup defines a cup volume 166 that is generally exposed to the arc chamber volume 116. The second opening 162B of the conduit 160, for example, is defined in a bottom surface 168 of the cup 164 and opens to the cup volume 166, whereby the source material 114 can be further transferred between the crucible volume 148 and the cup volume 166.

According to another example aspect of the disclosure, the cup 164 further defines, or is a component of, a repeller apparatus 184 operably coupled to the arc chamber 118. The repeller apparatus 184, for example, can be negatively biased with respect to the arc chamber 118 by a bias voltage 186 (e.g., 0-500 V) provided by a repeller power supply 188. For example, the bias voltage 186 (e.g., a repeller supply voltage) can be altered in response to changes in arc current, extraction current, or other factors for control purposes. The controller 138 of FIG. 1, for example, can control the bias voltage 186, input parameters to the beam-steering apparatus 124, and/or other parameters associated with the plasma 142 of FIG. 2, whereby an amount of power from the plasma can be controlled and provided to the source material 114 within the cup 164, thus raising its temperature high enough for a vapor pressure to sustain the plasma within the arc chamber 118. The bias voltage 186, for example, can be further provided, controlled, or augmented by an arc voltage 192 (e.g., 0-150 V) applied to a cathode 194 associated with the arc chamber 118.

A reactive gas delivery system 190, for example, can be further provided to introduce a reactive gas to one or more of the arc chamber volume 116 of the arc chamber 118 or the crucible volume 148 of the crucible 146. For example, the reactive gas provided by the reactive gas delivery system 190 may be chemically reactive (e.g., fluorine, chlorine) with the source material 114. The reactive gas delivery system 190, for example, can further increase efficiency of the ion source 110 by sputtering material that condenses on one or more walls 150 (also called sidewalls) that generally enclose the arc chamber 118 and convert the sputtered material back into the plasma 142.

For example, the inductive heater 152 may be utilized in conjunction with the reactive gas delivery system 190 to produce a volatile feed material. In one example, heating of the source material 114 above its melting point, such as heating of a pure metal, may be desirable due to a high melting point of a layer of a material (e.g., a metal oxide) associated with, or formed by, various reactions with the source material. Accordingly, in one example, the source material 114 may be pretreated with hydrogen gas provided by the reactive gas delivery system 190, whereby the hydrogen reduces the metal oxide back to the pure metal form of the source material. Furthermore, the inductive heating provided by the inductively heated dopant material source 144 of the present disclosure can yield a higher temperature of a liquid metal ion source containing various chemical compounds, thus allowing for controlling a production rate of a volatile feed material (e.g., metal halides) using various reactive gases such as one or more of H₂, Cl₂, Br₂, F₂, PF₃, PF₅, XeF₂, CF₄, CHF₃, SF₆, B₂F₄, SiF₆, GeF₄, NF₃, or other reactive gases, whereby the reactive gas delivery system 190 is configured to provide such a reactive gas to one or more of the arc chamber volume 116 of the arc chamber 118 or the crucible volume 148 of the crucible 146.

In accordance with another example of the present disclosure, the inductively heated dopant material source 144 is configured for the source material 114 comprising a metal having a high melting point, whereby the inductively heated dopant material source advantageously provides rapid heating and cooling of the source material via the above-described induction heater 152. For example, the source material 114 can comprise aluminum (Al) having a melting point of 660° C., whereby the aluminum can be melted in less than one minute at atmospheric pressure via the induction heater 152 (e.g., a 95 kHz, 250 Watt induction coil).

By utilizing such inductive heating of the source material 114, for example, a throughput of the ion implantation system 102 of FIG. 1 can be advantageously increased over conventional systems due, at least in part, to the rapid heating and cooling cycles associated with the induction heater 152. For example, using conventional resistance heating of a conventional LMIS (e.g., resistive elements in thermal conductive contact with the source material), a time of greater than 30 minutes is typical in order to reach 400° C. for a source material, while greater than 2 hours is typical to cool the source material back to 50° C. Due to minimal thermal mass and non-contact heating of the source material 114, cooling associated with of the induction heater 152 of the present disclosure is significantly shorter than that of a conventional resistance heater. Further, the inductive heating provided by the inductively heated dopant material source 144 of the present disclosure has a significantly greater energy efficiency when compared to conventional resistive heating.

In accordance with another example, the crucible 146 of the inductively heated dopant material source 144 may consist of a single material, or the crucible may be produced or formed as layered structure, as illustrated in FIG. 4, whereby an inner vessel 196 (e.g., a high temperature and high mechanical strength material) is generally surrounded by an outer shell 198 (e.g., a thermally isolating or substantially non-conductive material). The present disclosure, for example, contemplates crucible 146 comprising multiple layers comprising either oxide or non-oxide engineered ceramics. For example, the outer shell 198 of the crucible 146 may comprise, or consist of, an outer vessel material, such as a machinable glass ceramic (e.g., Macor® manufactured by Corning, Inc.), whereby the outer vessel material is configured to act as a thermal blanket around the inner vessel, thus reducing power loss due to radiation from high temperatures associated with the source material 114 being inductively heated by the induction coil 154.

The inner vessel 196, for example, may comprise, or consist of, an inner vessel material, such as Boron Nitride (also known as white graphite), Alumina, Silicon Carbide, Beryllium or Magnesium Oxide, various Zirconia-stabilized recipes or various other engineered ceramics. The inner vessel material and outer vessel material, for example, may be selected based on one or more of cost, purity, and process requirements.

The present disclosure contemplates various configurations of the crucible 146 based on various process conditions or requirements. For example, if a real-time estimate of an amount of the source material 114 present within the crucible 146 is not needed, the crucible may comprise an electrically conductive material. For example, the crucible 146 may be comprised of graphite or various other refractive metals or high temperature alloys, whereby a selection of such material may be based on the material being non-toxic to semiconductor processing.

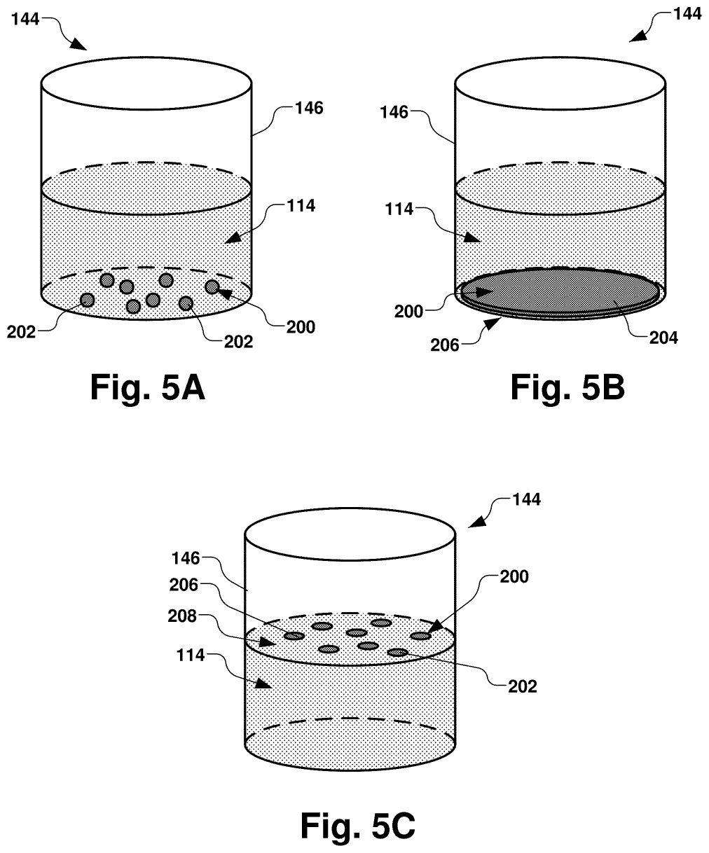

Due to unfavorable resistivity and magnetic properties of some metals that may be desirable for use as the source material 114, such metals may be difficult to melt by the above-discussed induction heating, alone. The present disclosure thus contemplates another example, whereby an intermediary receptor 200 is provided and favorably positioned within the crucible 146 of the inductively heated dopant material source 144, as illustrated in several examples shown in FIGS. 5A-5C. The intermediary receptor 200, for example, can be comprised of a material that is fabricated or otherwise formed from a refractory metal. In another example, the intermediary receptor 200 can be comprised of graphite. The intermediary receptor 200 of FIGS. 5A-5C, for example, can be advantageously utilized with the induction heater 152 of FIG. 2, for example, whereby the intermediary receptor can provide for indirect heating of the source material 114 when the source material is non-conductive (e.g., AICl₃, AlI₃, PtCl₂, or the like) or has low resistivity (e.g., Ga, Al, or the like).

In one example, the intermediary receptor 200 can have a density that is higher or lower than a target metal density associated with the source material 114 (e.g., the density of the metal species for the desired ionization). For example, the intermediary receptor 200 can be comprised of tungsten (W), molybdenum (Mo), tantalum (Ta) or the like. As such, the target metal density of the intermediary receptor 200 can force the intermediary receptor to remain at the bottom of the crucible, as illustrated in FIGS. 5A-5B. In one example, the intermediary receptor 200 may be comprised of a plurality of small bodies 202 (e.g., beads or pellets) illustrated in FIG. 5A, wherein the density of the plurality of small bodies is greater than the target metal density of the source material 114, thus forcing the plurality of small bodies to sink in the source material when the source material is in the molten or liquid state. FIG. 5B illustrates the intermediary receptor 200 as comprising a receptor plate 204, whereby the density of the receptor plate is similarly greater that the target metal density of the source material 114, thus forcing the receptor plate to sink in the source material when the source material is in the molten or liquid state. The receptor plate 204 of FIG. 5B may alternatively be fixedly coupled to a bottom wall 206 of the crucible 146, and can be of any density.

FIG. 5C illustrates another example of the intermediary receptor 200, the plurality of small bodies 202 have a lower density than the target metal density of the source material 114. For example, the plurality of small bodies 202 may be comprised of a low-density material such as porous graphite. As such, the plurality of small bodies 202 shown in FIG. 5C float freely on a surface 208 of the source material 114 when the source material is in a molten state. The present disclosure, for example, contemplates the plurality of small bodies 202 (e.g., free-floating beads or discs) floating on or near the surface 208 of the source material 114, whereby the plurality of small bodies are configured to vibrate under the influence of a rapidly varying electromagnetic field when the inductive heater 152 is activated. The vibration of the plurality of small bodies 202, for example, can effectively stir the source material 114 when the source material is in the molten state, thus breaking an oxide film (not shown) that may have formed thereon. Such a breaking of the oxide film, for example, is particularly beneficial when a solid slab of the source material 114 is present in the crucible 146 having an oxide film disposed or otherwise formed thereon.

In accordance with an example aspect of the disclosure, the inductively heated dopant material source 144 can be provided as a vaporizer when the source material 114 has a high vapor pressure. For example, the source material 114 can comprise magnesium (Mg), whereby the induction heater 152 can be configured to vaporize the magnesium at 420° C. (e.g., at a vapor pressure of approximately 7 mTorr). In other examples, the source material 114 can comprise various other metals or compositions, whereby the induction heater 152 of the present disclosure can be configured for vaporization and delivery of the source material for introduction to the arc chamber volume 116 in a vapor or gaseous phase without the use of a hydraulic feed system. For example, gallium (Ga) may be heated to 1027° C., tin (Sn) may be heated to 1127° C., indium (In) may be heated to 1100° C., or aluminum (Al) may be heated to 1127° C. via the induction heater 152, whereby the source material 114 may be directly supplied to the arc chamber 118 in the vapor phase without vaporization from a liquid phase being performed in the arc chamber volume 116.

The present disclosure further advantageously decreases a cost and complexity of the ion implantation system 102 of FIG. 1 by providing the inductively heated dopant material source 144 comprising the induction heater 152, whereby the ion implantation system can be made more robust while reducing an extraction current, thus reducing a rate of arc glitching. In some examples, the present disclosure contemplates supplying only atoms of a desired dopant species to the arc chamber volume 116 of the arc chamber 118 from the inductively heated dopant material source 144. For example, in a conventional resistively-heated LMIS, a dopant material is supplied in a liquid form to a conventional plasma chamber, whereby an etching chemistry is often used to liberate atoms of the desired dopant species from the liquid into the plasma formed within the conventional plasma chamber. In contrast, the inductively heated dopant material source 144 of the present disclosure is configured to provide higher temperatures to a pure metal by the aforementioned induction heater 152, whereby each atom entering the plasma 142 can be of the desired species, without the need of any additional etching chemistry.

Additional advantages and efficiencies are further contemplated by the present disclosure, whereby feedback associated with the inductively heated dopant material source 144 and/or ion implantation system 102 of FIG. 1 can be used to efficiently control the ion implantation system 102.

For example, the heating provided by the inductively heated dopant material source 144 of FIG. 1 advantageously further allows for temperature monitoring of the source material 114 in a molten form within the crucible 146. For example, the present disclosure appreciates that a power budget associated with the ion source 110 can be limited. As such, the present disclosure contemplates the controller 138 being configured to control a DC power supply 300 feeding an inverter 302 for providing an induction current 304 to the induction heater 152. The present disclosure appreciates that it can be advantageous to minimize power usage while ensuring stability of the ion beam 120, leading to a desire to optimize power consumption of the inverter 302 associated with the inductively heated dopant material source 144.

Accordingly, it can be desirable to regulate a temperature of the source material 114 in a molten form in order to meet various process requirements associated with the ion implantation system 102, as excessive heating can lead to a deleterious use of power. It is appreciated that a thermocouple or RTD (not shown), for example, can be difficult to implement in proximity to the induction heater 152 due to excessive heating of wiring associated with such a thermocouple or RTD. While a pyroelectric sensor (not shown) can be used, a direct line-of-sight from the pyroelectric sensor to the surface of the source material would desired, a pyroelectric optical window for providing such a line-of-sight can be contaminated by randomly deposited particles from the source material.

The present disclosure however, contemplates that a vapor pressure of the source material 114 is a function of a molten phase of the temperature 306 (e.g., a surface temperature) of the source material. As such, when other beamline parameters (e.g., variables associated with the terminal 104, beamline assembly 106, and end station 108) are fixed or otherwise known, a beam current 308 associated with the ion beam 120 is indicative of the temperature 306 of the surface that is in the molten phase.

Thus, the present disclosure contemplates a control scheme or control loop having an adaptive algorithm configured to compensate for a presence and a variability of various processing tool parameters that may otherwise affect an accuracy of the control loop in the ion implantation system 102. In one example, a Kalman Filter (e.g., linear quadratic estimation) may be implemented for the control loop, whereby various inputs (e.g., primary inputs, compensatory secondary inputs, etc.) to the control loop are contemplated.

For example, primary inputs to control loop may comprise one or more of a desired vapor pressure of the source material 114, a mode selection signal as being either self-resonating or a forced frequency, a current consumed by inverter 302 at predetermined voltage, and the beam current 308 measured by a Faraday cup 310 or other sensor positioned along a beamline 312 of the ion implantation system 102. In the present example, the Faraday cup 310 is positioned in the end station 108 of the ion implantation system 102, however other locations for measuring the beam current 308 along the beamline 312 are also contemplated.

Compensatory secondary inputs, for example, may comprise one or more of a vapor pressure that is measured in close proximity to the surface 208 of the source material 114, a temperature of the source material, an extraction voltage 314 applied to the extraction electrode 122, voltages and currents applied to various focusing and acceleration electrodes (not shown) upstream of the workpiece 128, a position of an extraction electrode, or numerous other inputs.

The present disclosure contemplates, in one example, a primary output from the control loop comprising an amount of the source material 114 remaining in the crucible 146, or other various outputs. For example, in accordance with an example of aspect of the present disclosure, the inductive heating provided herein by the inductively heated dopant material source 144 further allows for a monitoring of an amount of the source material 114 remaining in the crucible 146. For example, the present disclosure appreciates that an abnormally high usage of the source material 114 may be indicative of a problem, error, or mis-tuning of the ion implantation system 102 of FIG. 1, whereby if left unchecked, such problems may result in an unscheduled shutdown of the ion implantation system. When considering a fixed input voltage 316 to the inverter 302, a current usage of the inverter is linearly related to the amount of the source material 114 that is exposed to the electromagnetic field within the induction coil 154 of the induction heater 152.

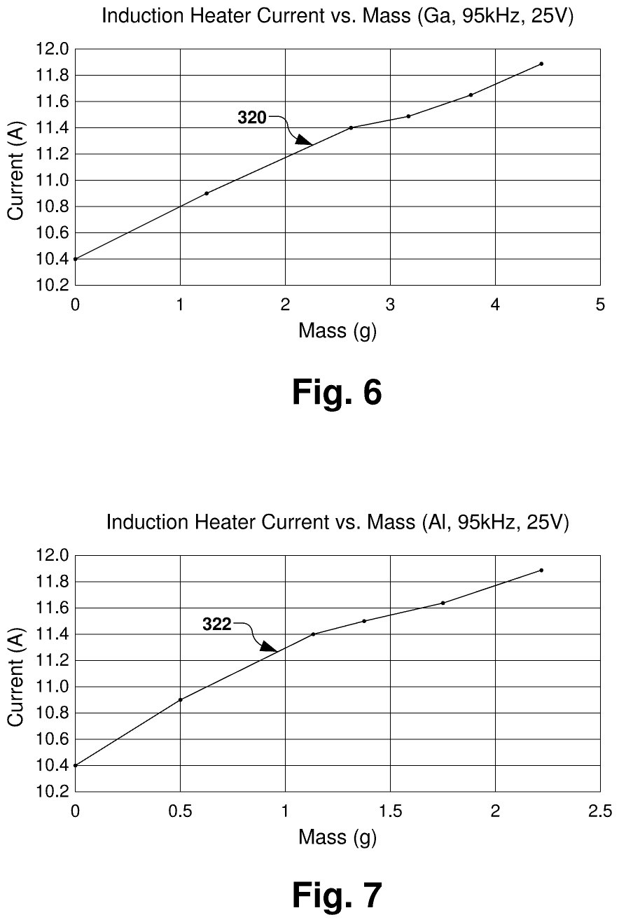

The controller 138, for example, can comprise a material monitoring system configured to determine an amount of the source material 114 contained in the crucible 146, wherein the amount (e.g., a mass) of the dopant species contained in the crucible is proportional to the induction current 304 supplied to the induction heater 152. FIG. 6, for example, illustrates a correlation 320 of the induction current 304 of FIG. 1 supplied to the induction heater 152 to the mass of the source material 114 contained in the crucible 146 when the source material comprises gallium at the fixed input voltage 316 of 25 volts and an induction frequency of 95 kHz. FIG. 7 illustrates another correlation 322 of the induction current 304 of FIG. 1 supplied to the induction heater 152 to the mass of the source material 114 contained in the crucible 146 when the source material comprises aluminum at the fixed input voltage 316 of 25 volts and an induction frequency of 95 kHz. As can be seen from the examples of FIGS. 6-7, the inverter current decreases generally linearly as the mass of the source material 114 decreases from being consumed by the ion source 110 of FIG. 1.

A reduction in the induction current 304, for example, can thus be utilized to serve as a function of an amount of the source material 114 remaining in the crucible 146. For example, an amount of the source material 114 remaining in the crucible 146 can be determined, once appropriate calibration or scaling of the induction current 304 is performed. Furthermore, in conjunction with an integral of the beam current 308, the induction current 304 may be used to mutually enhance both the measurement of the temperature 306 and material usage measurements using various model. For example, the controller 138 can be configured to use a Kalman Filtering algorithm (e.g., a linear quadratic estimation) as model enhancer.

According to still another aspect of the present disclosure, a control of an induction frequency 330 applied to the induction heater 152 by the inverter 302 is contemplated, whereby a selective control of the induction frequency can advantageously address various processing conditions or requirements associated with the ion implantation system 102.

For example, in one embodiment, the induction frequency 330 can comprise a high frequency (e.g., up to approximately 200 kHz at a 1.5 km wavelength) that can be provided to the induction heater 152 to promote rapid heating of the surface 208 of the source material 114. For example, the surface 208 of the source material 114, when in a solid bulk metal form, can act to improve a surface flow associated with the metal, as a solid-encapsulating melted metal layer can act as a lubricant, thus reducing surface friction between the still-solid bulk metal and a wall of a crucible 146. For example, while not shown, such a reduced surface friction between a heated, yet still solid metal core of the source material 114 can promote a forcing upward of the bulk metal when the crucible 146 is conically-shaped.

In another embodiment, the induction frequency 330 can comprise a low frequency (e.g., approximately 5 kHz at a 60 km wavelength) that can be provided to the induction heater 152 to slowly melt a sample in its bulk, while an introduction of higher melting point, process inert, and lower-density plurality of beads, such as the plurality of small bodies 202 of FIG. 5C can promote stirring, thus breaking a residual oxide layer. Furthermore, the present disclosure contemplates examples of the induction heater 152 of FIG. 1 as being self-resonating, or as a forced-frequency design.

The present disclosure thus further contemplates a control scheme or methodology for controlling one or more conditions (e.g., a temperature, quantity, etc.) of the inductively heated dopant material source 144. As such, the present disclosure not only provides an inductively heated dopant material source 144, but also a corresponding control scheme or loop.

Direct induction melting of the source material 114, such as a metal species suitable for ion implantation, offers several advantages, including, but not limited to material purity, and an increased capacity for the inductively heated dopant material source 144, thus maximizing up-time for the ion implantation system 102. Such advantages further lead to reductions in concentrations of toxic and aggressive byproducts, and provides an ability to deliver a significantly increased and well-controlled vapor pressure with increasing beam current. The present disclosure further provides tight control over the beam current, and can provide a determination or estimate of a remaining amount of the source material 114 remaining in the inductively heated dopant material source 144 in order to schedule service intervals for the ion source 110 or other components of the ion implantation system 102, as well as various other advantages.

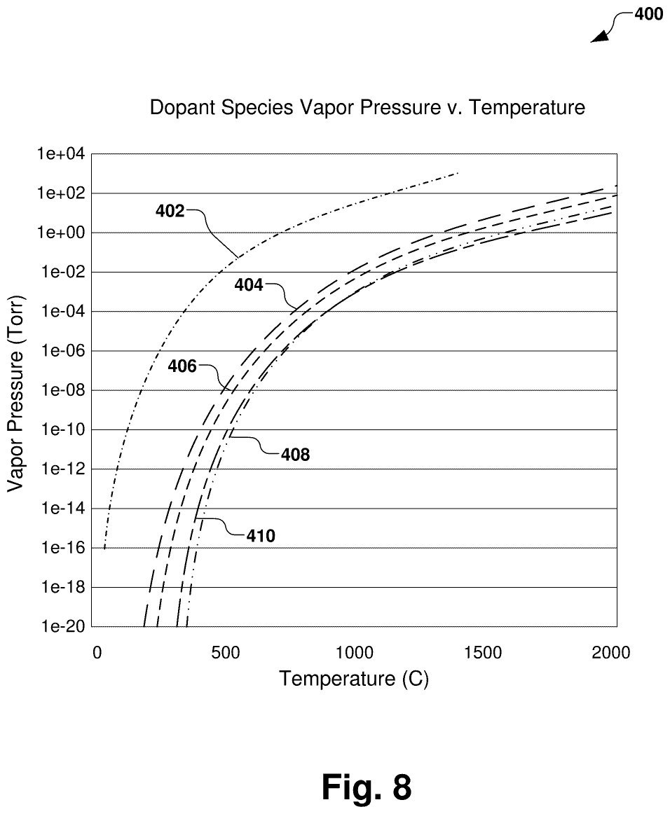

FIG. 8, for example, illustrates various vapor pressure curves for various metals, whereby various advantages of the inductive heating of the present disclosure can be further appreciated. For example, a temperature achieved by the inductive heating described in the above disclosure can be determined based on the vapor pressure curves 400 for magnesium 402, indium 404, gallium 406, tin 408, and aluminum 410, in conjunction with the control scheme provided in FIG. 1. The vapor pressure curves provided in FIG. 8, for example, can be utilized by the controller 138 of FIG. 1 to determine one or more of the temperature and amount of the source material 114 remaining in the crucible 146.

It is further noted that while inductive heating of the source material 114 is discussed in various aspects of the disclosure, the present disclosure further contemplates alternative use of the various inductive heating apparatuses in various examples described above. For example, various aspects discussed above are further contemplated in application in a preheating stage, an electrostatic chuck, or other applications in a semiconductor processing system. The present disclosure, for example, may be applied to various concepts related to inductively heating dopant source feed materials (e.g., source materials contained in a remote vaporizer).

Although the invention has been illustrated and described with respect to one or more implementations, alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. The term “exemplary” as used herein is intended to imply an example, as opposed to best or superior. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. An ion source comprising:
an arc chamber defining an arc chamber volume;
an inductively heated dopant material source in fluid communication with the arc chamber volume, wherein the inductively heated dopant material source comprises a crucible and an inductive heater, wherein the crucible is configured to contain a dopant species therein; and
an induction heater power supply electrically coupled to the inductive heater, wherein the induction heater power supply is configured to selectively supply an induction current to the induction heater; and
a controller configured to control the induction current via a control of the induction heater power supply, wherein the inductive heater selectively heats the dopant species to a predetermined temperature based, at least in part, on the induction current to selectively permit a flow of the dopant species from the crucible to the arc chamber volume.

2. The ion source of claim 1, wherein the crucible comprises an inner vessel configured to contact the dopant species, and wherein the inductive heater is configured selectively inductively heat the dopant species through the inner vessel.

3. The ion source of claim 2, wherein the crucible further comprises an outer shell generally surrounding the inner vessel, and wherein the inductive heater is configured selectively heat the dopant species through the outer shell.

4. The ion source of claim 3, wherein the inner vessel is comprised of a first ceramic, and wherein the outer shell is comprised of a thermally and electrically insulating material.

5. The ion source of claim 4, wherein one or more of the inner vessel and the outer shell comprises one or more of boron nitride, alumina, silicon carbide, beryllium oxide, magnesium oxide, zirconia, or a machinable glass ceramic.

6. The ion source of claim 1, further comprising a conduit, wherein the inductively heated dopant material source is positioned external to the arc chamber, wherein the conduit fluidly couples the inductively heated dopant material source to the arc chamber, and wherein the conduit is configured to introduce the dopant species to the arc chamber volume in one of a liquid phase or a vapor phase.

7. The ion source of claim 6, further comprising a cup positioned within the chamber arc volume, wherein the conduit is configured to introduce the dopant species to the arc chamber volume in the liquid phase.

8. The ion source of claim 6, wherein the inductively heated dopant material source comprises a vaporizer, wherein the inductive heater is configured to vaporize the dopant species at the predetermined temperature in the crucible within the vaporizer to define a vaporized dopant species, and wherein the conduit is configured to introduce the vaporized dopant species to the arc chamber volume.

9. The ion source of claim 1, further comprising a reactive gas source configured to selectively supply a reactive gas to the crucible, wherein the reactive gas is configured to react with a material associated with the dopant species, thereby purifying the dopant species.

10. The ion source of claim 9, wherein the reactive gas comprises one or more of H₂, Cl₂, Br₂, F₂, PF₃, PF₅, XeF₂, CF₄, CHF₃, SF₆, B₂F₄, SiF₆, GeF₄ or NF₃.

11. The ion source of claim 1, wherein the controller further comprises a material monitoring system configured to determine an amount of the dopant species contained in the crucible, wherein the amount of the dopant species contained in the crucible is associated with the induction current supplied to the induction heater.

12. The ion source of claim 11, wherein the material monitoring system comprises a Kalman Filtering algorithm to model the amount of the dopant species contained in the crucible.

13. The ion source of claim 1, further comprising an intermediary receptor positioned within the crucible, wherein the induction heater is configured to inductively heat the intermediary receptor, and wherein the intermediary receptor is configured to aid a melting of the dopant species within the crucible.

14. The ion source of claim 13, wherein the dopant species is electrically non-conductive, and wherein the intermediary receptor is electrically conductive.

15. The ion source of claim 13, wherein the intermediary receptor has a receptor density and the dopant species has a dopant density, wherein the receptor density is greater than the dopant density, and wherein the intermediary receptor comprises a receptor plate associated with a bottom of the crucible.

16. The ion source of claim 15, wherein the intermediary receptor comprises one of a refractory material or graphite.

17. The ion source of claim 15, wherein the intermediary receptor has a receptor density and the dopant species has a dopant density, wherein the receptor density is less than the dopant density, and wherein the intermediary receptor comprises a plurality of small bodies.

18. The ion source of claim 17, further comprising an electromagnetic field generator configured to generate an electromagnetic field associated with the crucible, wherein the plurality of small bodies are configured to vibrate based on a selective variation in the electromagnetic field provided by the electromagnetic field generator.

19. The ion source of claim 1, wherein the controller is further configured to control a frequency of the induction current, whereby the frequency controls a speed of the heating of the dopant species.

20. The ion source of claim 19, wherein the frequency is in one of a high frequency of approximately 200 kHz at a 1.5 km wavelength associated with a fast melting of the dopant species and a low frequency of approximately 5 kHz at a 60 km wavelength associated with a slow melting of the dopant species.
